(19) United States
(12) Patent Application Publication
(10) Pub. No.: US 2005/0082670 A1
(43) Pub. Date: Apr. 21, 2005

(54) Method for preapplying a viscous material to strengthen solder connections in microelectronic packaging and microelectronic packages formed thereby

(75) Inventors: Horatio Quinones, Carlsbad, CA (US); Liang Fang, San Diego, CA (US); Dave Ellis, San Marcos, CA (US); Erik Andrew Fiske, Carlsbad, CA (US); Thomas Laferl Ratledge, San Marcos, CA (US); Alec J. Babiarz, Encinitas, CA (US); Robert Ciardella, Rancho Santa Fe, CA (US)

Correspondence Address: WOOD, HERRON & EVANS, LLP (NORDSON), 2700 CAREW TOWER, 441 VINE STREET, CINCINNATI, OH, 45202, US

(73) Assignee: Nordson Corporation

(21) Appl. No.: 10/937,053

(22) Filed: Sep. 9, 2004

Related U.S. Application Data
(60) Provisional application No. 60/502,027, filed on Sep. 11, 2003.

(51) Int. Cl. H01L 23/48; H01L 29/40; H01L 23/52; H01L 21/44

(52) U.S. Cl. 257/737; 257/738; 257/780; 438/614

(57) ABSTRACT

Apparatus and methods for preapplying discrete amounts of underfill material of a component on a component substrate before the solder bumps of the component are joined by reflow with a packaging substrate to create a microelectronics package. The underfill material is preferably applied by a noncontact dispensing technique as discrete amounts at interstitial areas on an active surface of the component substrate defined between nearest-neighbor solder bumps. The underfill material forms a continuous meniscus of underfill material across the interstitial areas not occupied by the solder bumps and forms a collar encircling each of the solder bumps. The cured underfill material strengthens and improves the reliability of the solder joints formed by the bump reflow.

### FIELD OF THE INVENTION

This invention relates generally to microelectronic packaging and, more particularly, to preapplying a viscous material to solder bumps on a component before the solder bumps are reflowed to form a microelectronic package with a packaging substrate and microelectronic packages formed thereby.

### BACKGROUND OF THE INVENTION

In microelectronic packaging, components, such as semiconductor die or chips, are mounted on a packaging substrate, such as a printed circuit board or a leadframe. Typically, solder balls or bumps on the component are placed in registration with electrical bond pads or electrical traces on the packaging substrate and the solder bumps are then reflowed to create electrical and mechanical interconnections in the form of solder joints extending between the component and the packaging substrate. After the reflow process is complete, a space or gap is present between the component and the packaging substrate.

Filling the gap with an underfill material, such as an epoxy or another polymer that is liquid in an uncured state, improves the reliability of the interconnections. Typically, a precise mass of the underfill material is deposited in a substantially continuous manner onto the packaging substrate along one or more side edges of the component. The underfill material flows into the gap due to surface-tension wetting or capillary action and is subsequently cured. The cured underfill material makes the interconnections fatigue and creep resistant and also permits the package to withstand shock loads from handling, temperature cycling and drop testing with either static or dynamic loads. The presence of the cured underfill material also discourages dendrite growth and other moisture-based failure mechanisms potentially causing electrical shorting and component failure.

Although the cured underfill material improves package reliability, it hinders component removability and the important rework option. Generally, the process of reworking components is initiated by uniformly heating the packaging substrate to a temperature below the solder melting point. The component undergoing rework is spot heated to melt the solder joints and break down the underfill material. The chip is gripped mechanically and then sheared away from the packaging substrate. After residual solder and underfill material are cleaned from the packaging substrate, a new component can be aligned, bonded, reflowed and underfilled.

Reworkability is important for permitting a single faulty or defective component to be replaced or repaired on a packaging substrate, which usually carries multiple components. When a single component fails, significant cost savings is realized by removing the failed component, installing a substitute component or repairing the failed component and reinstalling it, and returning the packaging substrate to service.

As an alternative to capillary underfill processes, underfill material may be preapplied onto the component before the solder bumps are reflowed to create the solder joints between the component and the packaging substrate. In such no-flow underfill processes, a component carrying solder bumps is placed onto a packaging substrate at a location having a preapplied amount of underfill material. The solder bumps displace the underfill material and protrude through to make contact with the electrical bonding pads on the substrate. The underfill material is cured and the solder bumps are reflowed to create solder joints. Another conventional method of preapplying underfill material screen prints the underfill material directly onto the solder bumps so that the underfill material surrounds the base of each solder bump. Yet another conventional method of preapplying underfill material applies underfill material to the bond pads during the bumping process before pre-formed solder bumps are pressed through the underfill material to make electrical contact with the bond pads and to surround the base of each solder bump with underfill material.

However, in such no-flow processes, the preapplied underfill material should not contaminate the crown of the solder bumps as the electrical connections may never be effectively established, may have a high resistance, and/or may have a short life. These adverse outcomes are even more likely to be observed if the underfill material contains a filler, such as alumina or silica. Conventional preapplied underfill methods are highly susceptible to contaminating the crowns of the solder bumps with underfill material.

It would be desirable, therefore, to preapply underfill material to a component of a microelectronic package for reinforcing the solder bumps without contaminating the crowns of the solder bumps.

### SUMMARY

In accordance with an embodiment of the invention, a method of preapplying underfill material includes dispensing discrete amounts of underfill material onto a substrate in interstitial areas of the substrate defined between a plurality of solder bumps. The method further includes allowing the discrete amounts of underfill material to flow across the interstitial areas to the solder bumps for forming a continuous meniscus of non-uniform thickness on the substrate in the interstitial areas of the substrate defined between the solder bumps and curing the underfill material after the continuous meniscus is formed.

In accordance with another embodiment of the invention, a component of a microelectronics package comprises a substrate including an active surface, solder bumps carried by the active surface, and interstitial areas on the active surface defined between nearest-neighbor groups of the solder bumps. The component further comprises a layer of underfill material on the active surface surrounding the solder bumps, the layer of underfill material having a continuous meniscus shape of non-uniform thickness in each of the interstitial areas defined between said solder bumps. The layer of underfill material may include a collar surrounding a base of each solder bump and, in certain embodiments of the invention, the collar may thin in a concave shape with increasing distance from the base.

In accordance with principles of the invention, the reworkability of an underfilled component is improved without sacrificing, or otherwise compromising, the ability of the underfill material to provide solder joint reliability. The underfill material wets up the side of each solder bump. This wetting may produce a concave profile. In addition, a thin layer of underfill material may be present in the interstices or spaces between adjacent bumps. The thin layer may be continuous. However, the underfill material does not bridge the gap between the packaging substrate and component (i.e., does not contact the underside of the packaging substrate). Therefore, the underfill material does not have to be removed during rework and the component can be simply removed by heating and reflowing the solder joints. After removal, the solder bumps preferentially remain associated with the component, which averts the situation in which a portion of the solder bumps remain attached to the packaging substrate and another portion of the solder bumps remain attached to the component.

The cost of under bump metallization (UBM) on the bond pads, which requires numerous layers and processes to provide a solder wettable surface for the solder interconnects and a diffusion barrier to the underlying silicon, is lowered by providing a layer of underfill material in accordance with the principles of the invention. Specifically, the presence of the layer of underfill material strengthens the interface so that some or all of the layers of the UBM may be eliminated, which would reduce the cost of the UBM and process complexity by reducing the number of process steps required to form the UBM.

These and other objects and advantages of the present invention shall become more apparent from the accompanying drawings and description thereof.

### BRIEF DESCRIPTION OF THE FIGURES

The accompanying drawings, which are incorporated in and constitute a part of this specification, illustrate embodiments of the invention and, together with a general description of the invention given above, and the detailed description given below, serve to explain the principles of the invention.

FIG. 1 is a diagrammatic perspective view of a component inverted to receive the preapplied underfill material;

FIG. 2 is a top view showing the component and underfill material applied on the component in the spaces between nearest-neighbor solder bumps;

FIG. 3A is a cross-sectional view of a portion of FIG. 2; and

FIG. 3B is a cross-sectional view similar to FIG. 3A after the underfill material has migrated to the solder bumps.

FIG. 4 is a cross-sectional view similar to FIG. 3B in which the component is secured with a packaging substrate.

### DETAILED DESCRIPTION OF THE INVENTION

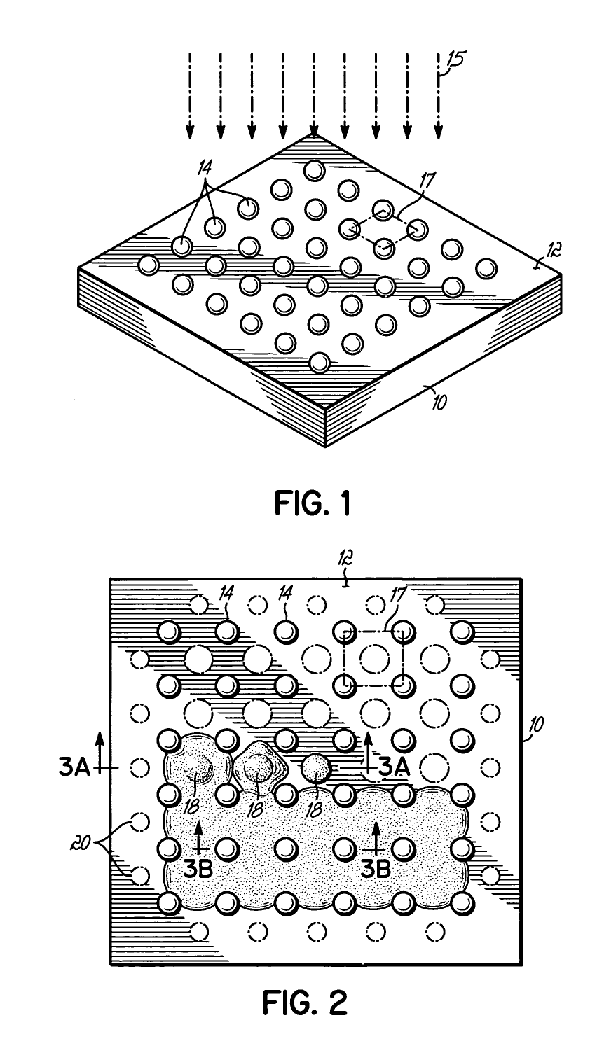

With reference to FIG. 1, a component 10, such as a semiconductor die or chip, includes a substrate 12 with an active surface that carries a plurality of solder balls or bumps 14 arranged in a matrix or an array, such as a ball grid array or a pin grid array. Typically, the array of solder bumps 14 is symmetrical and each bump 14 is hemispherical, although the invention is not so limited. The solder bumps 14 may be solder bodies of any conventional shape or construction description known by persons of ordinary skill in the art that join one surface to another leaving an air gap between the joined surfaces. The solder constituting the solder bumps 14 may be composed, for example, of a low melting point eutectic material or a high lead material. The solder bumps 14 may be formed or placed on the UBM-covered bond pads 16 by any suitable process, including but not limited to evaporation, electroplating, printing, jetting, stud bumping, and direct placement.

Before the underfill material is applied, the active surface of the component substrate 12 and the solder bumps 14 may be cleaned and treated by a surface modification process, such as plasma exposure indicated diagrammatically by arrows 15, for enhancing adhesion and wettability (hydrophilicity). This allows the fluid volume in each discrete amount 18, 20 (FIG. 2) of applied underfill material to be optimized for achieving a final mechanical structure. Specifically, the surface modification process induces the underfill material to move or wick more evenly or uniformly between bumps 14 and form a consistent profile. The consistent application also inhibits dendrite growth and protects the active surface of the component substrate 12. Suitable devices for plasma treating the component substrate 12 and solder bumps 14 include the FlexTRAK™, XTRAK™, and ITRAK™ automated plasma treatment systems commercially available from March Plasma Systems (Concord, Calif. and a subsidiary of Nordson Corporation (Westlake, Ohio)). Without being bound to any particular theory, surface modification by plasma treatment is believed to increase the surface energy of the active surface of component substrate 12 and add chemical function groups without changing the material properties of the bulk of component substrate 12.

The component 10 is inverted so that the active surface of component substrate 12 faces upwardly toward an underfill dispenser (not shown). Typically, the component 10 is heated to a temperature of about 60° C. to about 100° C. during dispensing, which enhances wicking or flow of the underfill material to the solder bumps 14.

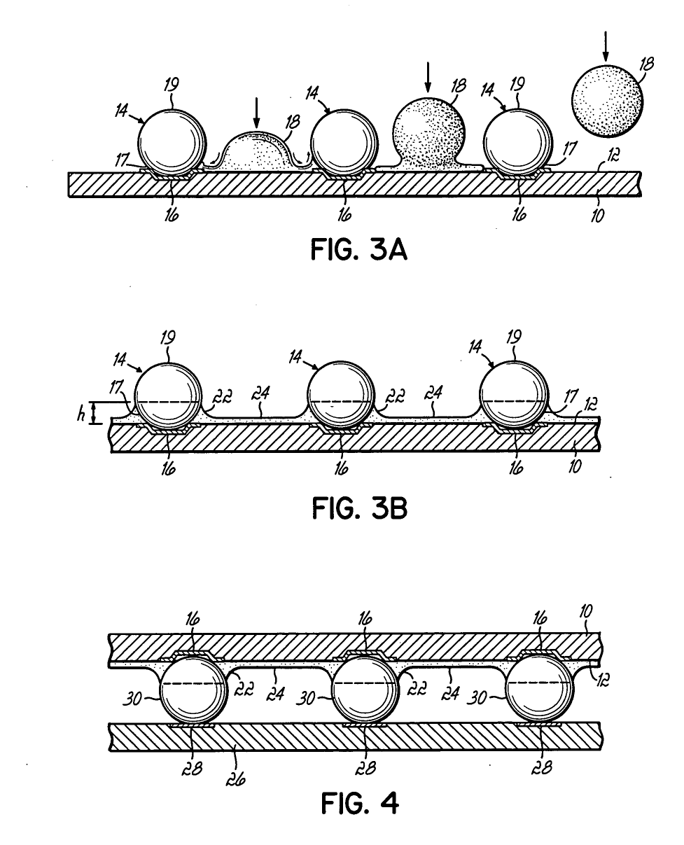

With reference to FIG. 3A, each of the solder bumps 14 projects outwardly from the active surface of the component substrate 12. Each solder bump 14 includes a base 17 proximate to the active surface of the component substrate 12 and a crown 19 opposite the base 17. The crown 19 constitutes the wettable solder region during the reflow process. The base 17 has a lower portion bonded with an underlying UBM-covered bond pad 16 of component substrate 12 and is coupled with the back-end-of-line (BEOL) interconnect structure of the component 10 by these bonds. The UBM-covered bond pads 16 are generally cup-shaped with a raised or inclined annular perimeter region and a flat central region radially inside the perimeter region.

With reference to FIGS. 2 and 3A, a plurality of streams or discrete amounts 18 of underfill material are applied to the component 10 at a corresponding plurality of target zones or locations on the active surface of component substrate 12. The discrete amounts 18 typically have a substantially uniform mass or volume, although the invention is not so limited. About the outer periphery of the bump array, a plurality of discrete amounts 20 of underfill material are applied to the active surface of component substrate 12 at a corresponding plurality of target zones or locations. The discrete amounts 20 typically have a substantially uniform mass or volume, although the invention is not so limited. Generally, the mass or volume of underfill material in discrete amounts 20 is less than the mass or volume of underfill material in discrete amounts 18 to preserve uniformity of the underfilling as discrete amounts 20 are serving as a reservoir for a smaller number of solder bumps 14 than discrete amounts 18. Stated differently, the discrete amounts 18 are distributed to larger number of nearest-neighbor solder bumps 14 than discrete amounts 20. Each discrete amount 18, 20 of underfill material is applied to the component substrate 12 at its target location with a spatial precision that avoids wetting the crown 19 of each solder bump 14. Discrete amounts 18, 20 of underfill material to be applied prospectively are indicated in phantom in FIG. 2.

Typically, the discrete amounts 18, 20 are each applied to the active surface of component substrate 12 substantially equidistant from a surrounding set of nearest-neighbor solder bumps 14. The target location of each discrete amount 18 may be at, or near, the geometrical center between the nearest-neighbor solder bumps 14 and the target location of each discrete amount 20 may be at, or near, the midpoint between adjacent pairs of solder bumps 14, although the invention is not so limited. The invention contemplates that each of the discrete amounts 18 and each of the discrete amounts 20 may be dispensed at each target location on the active surface of component substrate 12 as multiple dispensed volumes of underfill material. The invention further contemplates that some of the discrete amounts 18 or discrete amounts 20 may be omitted so that the dispensed array of underfill material is asymmetrical.

In the air gap separating the discharge outlet of the underfill dispenser (not shown) and the active surface of the component substrate 12, each discrete amount 18, 20 of underfill material has the general shape of a drop or droplet or may have the form of an interrupted stream. As each discrete amount 18, 20 strikes the active surface of the component substrate 12, the discrete amount 18, 20 deforms and flattens with individual portions that flow outwardly toward the nearest-neighbor or adjacent solder bumps 14. The leading edge of the flowing underfill material wets each of the nearest-neighbor solder bumps 14 and, then, additional underfill material from the discrete amount 18, 20 wicks or migrates toward the wetted solder bumps 14. Typically, equal portions of the discrete amounts 18, 20 flow to the surrounding group of nearest-neighbor solder bumps 14, although the invention is not so limited. The underfill material contacts and wets, due to surface tension effects, up the base 17 of each solder bump 14 to a given height above the active surface of component substrate 12. The invention contemplates that each of the discrete amounts 18, 20 may be dispensed as multiple individual droplets or interrupted streams at each target location, rather than as a single droplet or stream.

With continued reference to FIGS. 2 and 3A and in accordance with one embodiment of the invention, each of the solder bumps 14 is encircled or ringed by a set of target locations at each of which one of the discrete amounts 18, 20 of underfill material is applied over a relatively brief time interval. Each of the discrete amounts 18, 20 of underfill material behaves as described above, namely wetting and being distributed to the nearest-neighbor set of solder bumps 14. As a result, portions of the discrete amounts 18, 20 dispensed at each set of target locations ringing each solder bump 14 coalesce or combine at the solder bump 14.

With reference to FIGS. 2 and 3B, after the discrete amounts 18, 20 are dispensed at the target locations and wicking to the solder bumps 14 has occurred, a nonuniformly-thick plane or web 24 of underfill material is formed on the active surface of component substrate 12. The web 24 includes a plurality of collars 22 each surrounding the base 17 of one of the solder bumps 14. Collar 22 may have any suitable shape but is typically dimple-shaped, concave or meniscus-shaped. Preferably, each collar 22 contains a substantially uniform mass of underfill material and the collars 22 are geometrically uniform so that each solder bump 14 has a substantially uniform reinforcement. Typically, each collar 22 thins with increasing distance from the base 17 of the solder bump 14. Typically, portions of web 24 between the collars 22 constitute a continuous layer of uniformly thick underfill material, as depicted shown in FIG. 3B, and the collars 22 contribute the nonuniformity in thickness. However, it is apparent to persons of ordinary skill in the art that web 24 may constitute a continuous layer of nonuniformly-thick underfill material between collars 22 or may be discontinuous with certain surface areas on the active surface of component substrate 12 being uncovered. In certain embodiments of the invention, the web 24 of underfill material may be considered to form a continuous meniscus on the active surface of component substrate 12 that thins from the interface with collars 22.

The dispensed discrete amounts 18, 20 of underfill material are controlled such that the crown 19 of each hemispherical solder bump 14 is not wetted by underfill material originating from the dispensed discrete amounts 18, 20. As a result, the crown 19 of each solder bump 14 remains substantially free of underfill material after the collars 22 are formed. Generally, the height, h, of wetting from the coalesced discrete amounts 18, 20 of underfill material is limited to less than about 70% of the bump height above the active surface of component substrate 12, which means that the crown 19 constitutes the upper 30% of the bump height. For example, at least about 6 mils of a 23 mil-high solder bump 14 should be exposed after the conclusion of the underfill application in order to provide effective and reliable solder joints following reflow. The absence of underfill material from the crowns 19 improves the reliability of the electrical interconnections subsequently formed by the reflow process.

The underfill material on component substrate 12 is cured, typically by heating to a sufficiently high temperature, to a hardened state that strongly adheres to the solder bumps 14 and to the active surface of the component substrate 12. The cured underfill material mechanically reinforces the solder joints, once formed, for reducing the stress concentration and the presence of the web 24 of underfill material with collars 22 encircling the base 17 of each solder bump 14 to ensure that the solder joints are evenly reinforced. The web 24 of cured underfill material enables the solder joints to form a mechanical structure that better distributes the energy imparted to it (i.e., strain), which adds to the reliability of the assembled microelectronics package. In certain embodiments of the invention, the presence of the underfill material strengthens the solder joints such that some or all of the layers of the UBM on bond pads 16 may be eliminated.

The underfill material may be a liquid epoxy or any other suitable liquid polymer in an uncured state. Underfill materials suitable for use in the invention are available commercially from various suppliers including, but not limited to, Emerson & Cuming (Billerica, Mass.) and Henkel Loctite Corp. (Rocky Hill, Conn.).

With reference to FIG. 4, the component 10 is secured with a packaging substrate 26 in a subsequent process step to form a microelectronic package. Specifically, the component 10 is aligned with the packaging substrate 26 so that the solder bumps 14 (FIG. 3B) on the component substrate 12 are registered with bond pads 28 on the packaging substrate 26 and then, the solder bumps 14 are reflowed to create solder joints 30 that supply electrical and mechanical interconnections between the component 10 and packaging substrate 26. The reflow process does not affect or otherwise degrade the character of the cured web 24 of underfill material. The invention contemplates that the component 10 and packaging substrate 26 may be passed through a reflow furnace or some other heating mechanism to form solder joints 30 as well as curing the underfill material in web 24 by suitable selection of a temperature profile in the reflow furnace.

The pre-applied underfill material may be applied to the active surface of component substrate 12 using any suitable noncontact dispensing apparatus (not shown) capable of high volumetric accuracy and high spatial accuracy. For example, the underfill material may be applied using dispensing apparatus of the type commercially available from Asymtek Automated Dispensing Systems (Carlsbad, Calif. and a subsidiary of Nordson Corporation (Westlake, Ohio)), wherein the underfill material is jetted to the component substrate 12. A particularly useful dispensing apparatus is an Asymtek Axiom™ X-1020 system equipped with the DispenseJet® valve, which may be used to jet streams, drops or droplets of underfill material. Other dispensing apparatus suitable for use in the invention are shown in U.S. Pat. No. 5,913,455, the disclosure of which is hereby incorporated by reference herein in its entirety. The dispensing apparatus may be arranged in-line with the plasma treatment system, which allows the underfill dispensing to be performed individually and immediately after the surface modification process.

Generally, these types of dispensing apparatus include a jet with a pneumatically-actuated plunger cycled in a reciprocating manner against a valve seat separating a fluid chamber from a discharge passageway. Droplets or streams of underfill material, which can be heated in the discharge passageway, are dispensed by retracting the plunger from contact with the valve seat, allowing the underfill material to flow into the discharge passageway, and then moving the plunger rapidly toward the valve seat to close the dispensing apparatus. A discrete amount 18 of underfill material is forced to flow through the discharge passageway and is ejected from an outlet of the discharge passageway as a droplet or stream that is propelled toward the component substrate 12. Generally, the outlet is positioned at about twice the height of the solder bumps 14, which is generally about 0.7 mm to about 1 mm above the active surface of the component substrate 12, as the discrete amounts 18, 20 (FIG. 2) of underfill material are dispensed. The dispensing apparatus is rastered or moved to the central and peripheral locations necessary to dispense the full complement of discrete amounts 18, 20.

While the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. The invention in its broader aspects is therefore not limited to the specific details, representative apparatus and methods, and illustrative examples shown and described. Accordingly, departures may be made from such details without departing from the spirit or scope of applicants' general inventive concept. The scope of the invention itself should only be defined by the appended claims, wherein we claim:

1. A component of a microelectronics package, comprising;
a component substrate including a plurality of solder bumps, and a plurality of interstitial areas defined between the solder bumps; and
a layer of underfill material on said component substrate surrounding said solder bumps, said layer of underfill material having a continuous meniscus shape of non-uniform thickness in each of said interstitial areas defined between said solder bumps.

2. The component of claim 1 wherein each of said solder bumps includes a base adjacent to said component substrate, and said layer of underfill material includes a plurality of collars each surrounding said base of one of said solder bumps.

3. The component of claim 2 wherein each of said collars thins with increasing distance from said base.

4. The component of claim 3 wherein each of said solder bumps includes a sidewall extending away from said base, and each of said collars extends up said sidewall with a concave shape.

5. The component of claim 1 wherein said component substrate further includes a plurality of bond pads each joined with one of said solder bumps at an interface.

6. The component of claim 5 wherein said interface between each of said bond pads and a corresponding one of said solder bumps is free of underbump metallurgy layers.

7. A microelectronics package comprising the component of claim 1 and a packaging substrate having a plurality of bond pads joined with said solder bumps to define a corresponding plurality of solder joints.

8. The microelectronics package of claim 7 wherein said layer of underfill material does not contact said packaging substrate after said bond pads are joined with said solder bumps.

9. A method of preapplying underfill material to a component substrate having a plurality of solder bumps and a plurality of interstitial areas defined between the solder bumps, comprising:
dispensing a plurality of discrete amounts of underfill material onto the component substrate in the interstitial areas of the component substrate defined between the solder bumps;
allowing the discrete amounts of underfill material to flow across the interstitial areas to the solder bumps for forming a continuous meniscus of non-uniform thickness on the component substrate in each of the interstitial areas of the component substrate defined between the solder bumps; and
curing the underfill material.

10. The method of claim 9 further comprising:
modifying the component substrate with a surface treatment before applying the plurality of discrete amounts of underfill material.

11. The method of claim 10 wherein modifying the component substrate further comprises:
exposing the component substrate to a plasma.

12. The method of claim 9 wherein dispensing the plurality of discrete amounts of underfill material further comprises:
dispensing the plurality of discrete amounts by a non-contact dispensing method.

13. The method of claim 9 wherein each of the interstitial areas is defined between a nearest-neighbor group of the solder bumps.

14. The method of claim 9 wherein each of the solder bumps includes a base adjacent to the component substrate and a crown opposite to the base, and dispensing the discrete amounts of underfill material further comprises:
dispensing the discrete amounts of underfill material onto the component substrate without contaminating the crown of each of the solder bumps.

15. The method of claim 9 further comprising:
contacting the solder bumps with a corresponding plurality of bond pads on a packaging substrate; and
reflowing the solder bumps to establish a solder joint with the corresponding one of the bond pads.

16. The method of claim 9 wherein the component substrate includes a plurality of bond pads, and further comprising:
establishing a solder joint between one of the bond pads and each of the solder bumps before the discrete amounts of underfill material are applied.
